(19) United States
(12) Patent Application Publication
(10) Pub. No.: US 2011/0256823 A1
(43) Pub. Date: Oct. 20, 2011

(54) DATA CENTER CEILING

(75) Inventor: Bernard Ludmann, Austin, TX (US)

(73) Assignee: International Business Machines Corporation, Armonk, NY (US)

(21) Appl. No.: 12/909,281

(22) Filed: Oct. 21, 2010

(30) Foreign Application Priority Data
Dec. 2, 2009 (FR) EPO9306168.9

(51) Int. Cl. H05K 5/00

(52) U.S. Cl. 454/184

(57) ABSTRACT

A datacenter deck element and a datacenter comprising the same, comprising a remotely actuated louvre or slatted aperture. The slats are actuated to adopt a vertical position in the event of a fire so as to permit the passage of water from a sprinkler or other ceiling mounted extinguisher. In normal circumstance the angle of the slats in controlled so as to establish desired coolant air flow conditions in the datacenter. The slats are preferably transparent so as to avoid interference with ceiling mounted lighting. The slats are preferably conductive or conductively coated so as to remove static charge form the air flowing through the aperture. The slats may be independently actuated, or actuated in separate groups so at to adopt different configurations. The slats may in particular be set in two groups at opposing angles so as to split the air flow and encourage a laminar rather than a Brownian movement of air in an adjacent volume.

### RELATED APPLICATION

This Application is based on and claims the benefit of Priority from European Patent Application EP03906168.9 filed Dec. 2, 2009.

### FIELD OF THE INVENTION

The present invention relates to the construction of the ceiling of dacacenters, in particular with regard to provisions for the flow of air etc.

### BACKGROUND OF THE INVENTION

The provision of cool air and evacuation of heated air to ensure the efficient cooling of data centers in an area of increasing concern.

FIG. 1 shows a first conventional data center coolant path as known from the prior art. As shown in FIG. 1 a datacenter is arranged in parallel alternating hot aisles 131, 132 and cold aisles 101, 102, with articles of computer hardware an the like 111, 112, 113 arranged with their air inlets oriented so as to draw cool air 150 in from a cool aisle, and to expel it as heated air 160 into a respective hot aisle. As shown, cool air arrives in the cool aisles via an under-floor conduit and a grill in the datacenter floor, and hot air, having passed through the computer hardware and having been heated thereby is gathered at the ceiling above the computer hardware for expulsion.

As the density of computer hardware increases and the amount of heat energy dissipated rises, it becomes desirable to improve the thermodynamic efficiency of the cooling arrangement, for example reducing the possibilities for air to leak between the hot and cool aisles without passing through the computer hardware.

FIG. 2 shows a shows an improved conventional data center coolant path as known from the prior art. The datacenter of FIG. 2 is identical to that of FIG. 1, except that there are further provided decks 241, 242, which isolate the cool aisles from the hot aisles. As shown the decks are laid across the tops of the computer hardware units 111, 112, leaving gaps above the hot aisles so that hot air can escape upward towards the ceiling. It will be appreciated that the approach of providing a “false ceiling” for the outward flow of hot air, with baffles or dividers hanging downward to the computer hardware so that only the hot aisles can exhaust air through vents in the false ceiling is entirely equivalent.

A further trend in high power density datacenters actively extract hot air in the hot aisle and expel it to the outside air or direct it to a distant area where the air can be cooled, to maintain the best energy efficiency.

This extraction is carried out by done by establishing a partial vacuum above the hot aisle, or by pressurising cool air arriving via open tiles on the floor.

### SUMMARY OF THE INVENTION

According to the present invention there is provided a datacenter deck element as defined in the appended independent claim 1 and a datacenter as defined in the dependent claim 11. Preferred embodiments are defined in the dependent claims.

The present invention improves the efficiency with which high power density Datacenters are cooled, leading to savings in energy consumption. The present invention furthermore improves effective sprinkler action—safety—when a danger is detected—the sprinkler is able to perform its action in priority versus aisle containment activity and provides flexible control of upward and downward air flows, to mix air energy transport in a top/down direction.

Further advantages of the present invention will become clear to the skilled person upon examination of the drawings and detailed description. It is intended that any additional advantages be incorporating therein.

### BRIEF DESCRIPTION OF THE DRAWINGS

Embodiments of the present invention will now be described by way of example with reference to the accompanying drawings in which like references denote similar elements, and in which:

FIG. 1 shows a first conventional data center coolant path as known from the prior art;

FIG. 2 shows a shows an improved conventional data center coolant path as known from the prior art;

FIG. 3 shows a datacenter incorporating a first embodiment;

FIG. 4 shows a first datacenter deck element configuration in cross section according to an embodiment;

FIG. 5 shows a second datacenter deck element configuration in cross section according to a further embodiment;

FIG. 6 shows a third datacenter deck element configuration in cross section according to a further embodiment;

FIG. 7 shows the flow of air through a datacenter deck element in accordance with an embodiment;

FIG. 8 shows the flow of extinguisher fluid through a datacenter deck element in accordance with an embodiment.

FIG. 9 shows a first configuration of a datacenter deck element adapted to promote laminar airflow;

FIG. 10 shows a second configuration of a datacenter deck element adapted to promote laminar airflow; and

FIG. 11 shows a second configuration of a datacenter deck element adapted to promote laminar airflow.

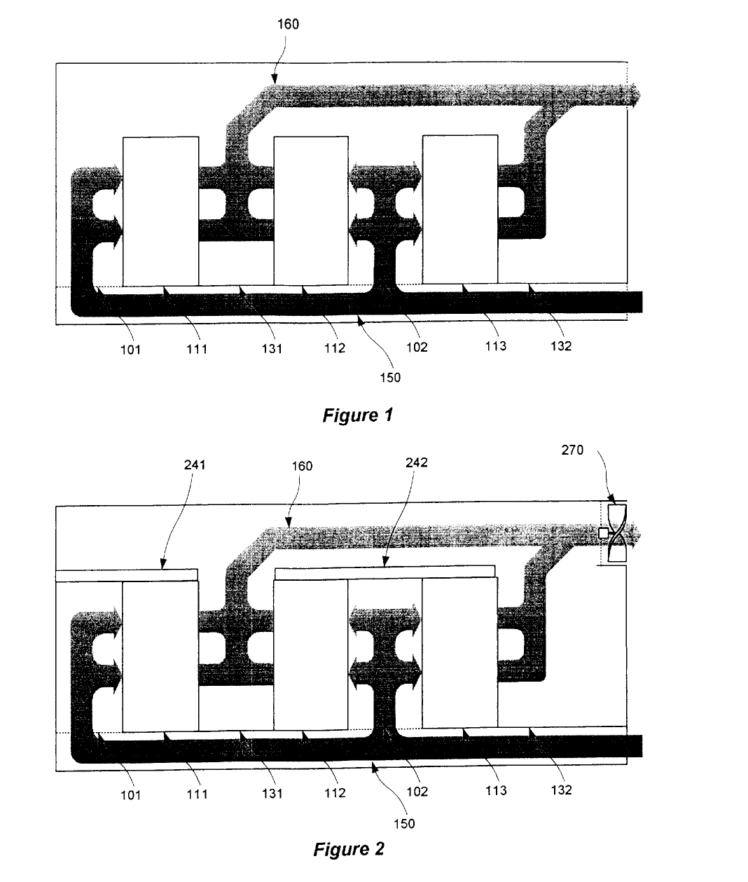

### DETAILED DESCRIPTION OF THE PREFERRED EMBODIMENT

While the use of decks as described above, a false ceiling or other structure above the computer hardware in a datacenter provides a valuable means to control airflow and effectively reduce leakage between cool and hot aisles, the installation of such structures can have a negative impact on other aspects of datacenter infrastructure. In particular, such structures by their very nature tend to interfere with the functioning of any ceiling mounted equipment or any other equipment that might be mounted above the computer hardware. Examples of such equipment include fire extinguishers such as water sprinkers, inert gas valves etc, smoke or flame detectors, lighting etc.

In particular, with such decks, classical sprinklers cannot work on the enclosed area of the data center, or need to be redirected or extended under the aisle deck with many risks of not working properly.

In the industry the safety rules says that sprinkler needs to be at least 80 cm above each obstacle and any surface must be able to receive water in case of a fire or smoke alert.

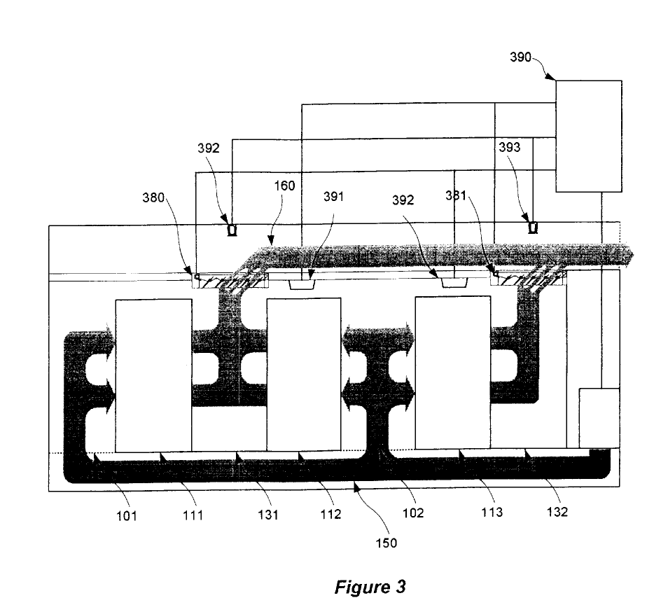

FIG. 3 shows a datacenter incorporating a first embodiment. In particular, as shown there is provided a datacenter comprising one or more pieces of computer hardware 111, 112, 113, one or more datacenter deck elements 380, 381, each comprising a substantially planar member comprising an aperture, a plurality of slats each said slat rotatable about a longitudinal axis, the axes of said slats being arranged in parallel in the plane of the member, actuating means coupled to said slats so as to cause said slats to rotate about their respective axes, such that in a first configuration the surfaces of adjacent slats touch substantially closing said aperture, and in a second position the surfaces of adjacent slats are separate leaving said aperture at least partially open,

wherein said actuating means is adapted to cause said slats to rotate in response to a remote control signal.

These datacenter deck elements 380, 381 are situated above the pieces of computer hardware 111, 112, 113. there are further provided control means 390 in communication with the datacenter deck elements 380, 381 and adapted to control the actuating means of each datacenter deck element as a function of conditions in the datacenter. In particular as shown the control means 390 is in communication with smoke detectors 391, 392, and is accordingly adapted to set at least one of the one or more datacenter deck elements to the second configuration in which the surfaces of adjacent slats are separate leaving said aperture at least partially open.

The structure of the datacenter deck elements and in particular the actuating mechanism may be implemented in a wide range of manners as will occur to the skilled person.

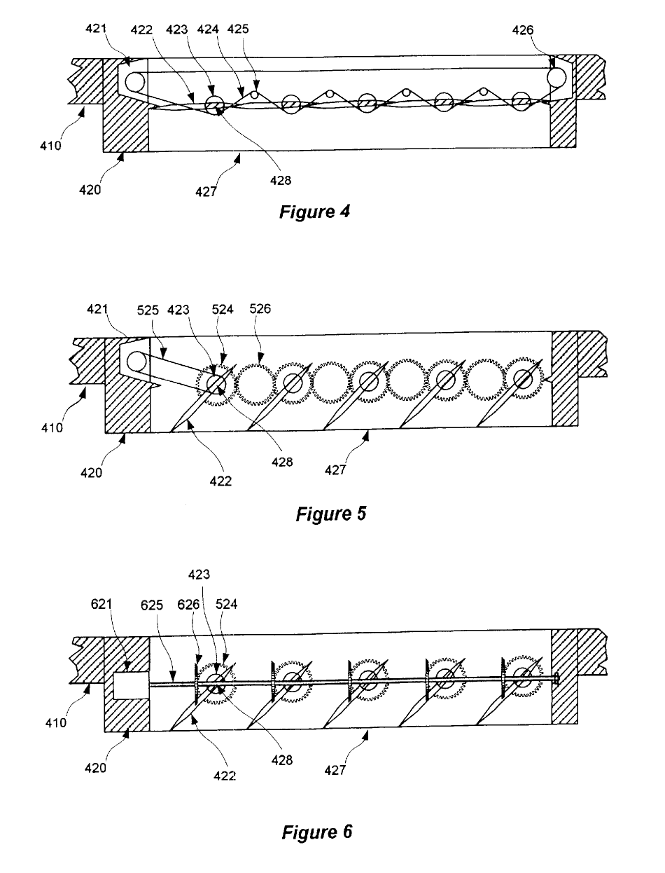

FIG. 4 shows a first datacenter deck element configuration in cross section according to an embodiment. As shown in FIG. 4 there is provided a datacenter deck element comprising:

a substantially planar member 410, said substantially planar member comprising an aperture 427,
a plurality of slats 422 each said slat 422 rotatable about a longitudinal axis 428, the axes of said slats being arranged in parallel in the plane of said member 410,
actuating means in the form of a motor 421 coupled to said slats 422 by a drive belt or band 424 engaging wheels 423 mounted on the axis of each slat 422. In order to maintain tension in the band on each wheel 423 there are provided tensioning idlers 525. By the action of the motor 421 via the drive belt 424 the wheels 423 and hence the slats 422 can be caused to rotate about there respective axes in either a clockwise or anticlockwise direction as required. By this means the slats can be set at any angle permitted by there situation with respect to the housing and neighbouring slats. Specifically, there is preferably a first configuration in which the surfaces of adjacent slats touch, substantially closing said aperture. There is further a second configuration in which the surfaces of adjacent slats are separate leaving said aperture at least partially open. As shown in FIG. 4 the slats 422 are in the first configuration, with the tip of each slat touching the opposite tip of the neighbouring slat, so that the aperture 427 is substantially blocked. The motor 421 is responsive to a remote control signal. The motor may be a servo motor, stepper motor, an AC motor or any other kind of electric motor, and may incorporate a network interface, digital or analog command decoder as required. The remote control signal may be a digitally or analogue coded control signal, or may simply comprise a AC or DC voltage of suitable duration, polarity and duration to bring about the desired change in position.

FIG. 5 shows a second datacenter deck element configuration in cross section according to a further embodiment. As shown in FIG. 5 there is provided a datacenter deck element substantially as described with respect to FIG. 4. As shown in FIG. 5, the motor 421 is coupled to the first, nearest slats 422 by a drive belt or band 525 engaging a wheel a mounted on the axis of that first slat 422. There is further provided a first gear 524 mounted on the axis of the first slat. Each slat is similarly provided with a gear mounted on its respective axis. There are furthermore provided secondary gears 526, each situated between, and engaging two adjacent first gears. When actuated, all of the first gears rotate in one direction, and the second gears rotate in the opposite direction. Thus by the action of the motor 421 via the drive belt 525 the gears 524 and hence the slats 422 can be caused to rotate about their respective axes in either a clockwise or anticlockwise direction as required. By this means the slats can be set at any angle permitted by there situation with respect to the housing and neighbouring slats.

As shown in FIG. 5 the slats 422 are in the second configuration, wherein the surfaces of adjacent slats are separated leaving said aperture at least partially open. As shown the slats are at an angle of approximately 45° with respect to the plane of the substantially planar member 410. According to a preferred embodiment the said second position said slats are substantially orthogonal the plane of said member.

FIG. 6 shows a third datacenter deck element configuration in cross section according to a further embodiment. As shown in FIG. 6 there is provided a datacenter deck element substantially as described with respect to FIG. 4. As shown in FIG. 6, the motor 621 is oriented at right angles to the motors 421 described with respect to FIGS. 4 and 5, and is coupled to the slats 422 by a drive shaft 625 extending at right angles to the axes of the slats 422, in the plane of the axes of the slats. First crown gears 626 are situated on the drive shaft at regular intervals corresponding to the distance between the respective axes of the slats. A second crown gear is mounted on the axis of each slat, and engages a respective first crown gear on the drive shaft. When the motor 621 turns, it directly turns the drive shaft, and via the engagement of the pair of crown gears provided for each slat, causes the slats 422 to rotate about their respective respective axes in either a clockwise or anticlockwise direction as required.

There may be defined one or more further configurations which may be appropriate for other situations, or indeed any arbitrary angle may be selected. For example, in some embodiments it may be desired to control the angle of the slats to attain any arbitrary angle or one of a plurality of different preset angles so as to vary the obstacle presented by the slats to the passage of air through the aperture 427.

As shown, the slats are asymmetrical with respect to their respective axes. By this means in the absence of actuation the slats will tend to adopt the second position wherein the slats are substantially orthogonal the plane of the planar member, i.e. with the edge of the slat extending furthest from the axis hanging downward. By this means the slats operate in a fail-safe manner, such that in the event of an actuation failure, for example in the case of a power cut, motor failure or mechanical problem, the slats will tend to open so as to permit the flow of air and extinguisher fluid. Still further, an component of the actuation mechanism may be formed of a heat sensitive material such that in the event of an controlled fire the actuation mechanism will be disengages from the slats by the melt, softening or deformation of this heat sensitive component, allowing the slats to adopt their default position.

The datacenter deck element may preferably be constructed such that while the actuation mechanism can biased the slats away from the second position substantially orthogonal the plane of the planar member, this may be by means of a resilient element or a clutch mechanism such that a minimal force, such as the incidence of extinguisher fluid on the uppermost surfaces of the slats, is sufficient to overcome the actuation force and return the slats to the second position substantially orthogonal the plane of the planar member, thereby allowing the free flow of such extinguisher fluid downward despite the absence of a explicit actuation to this effect.

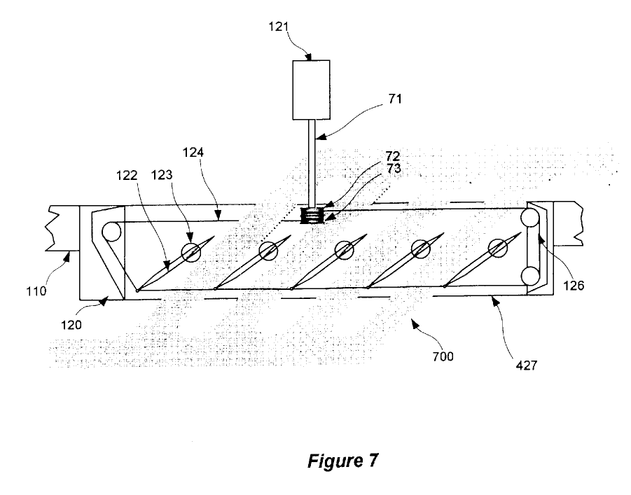

FIG. 7 shows the flow of air through a datacenter deck element in accordance with an embodiment. As shown, there is provided a datacenter deck element substantially as described with regard to FIG. 4.

As shown the actuation means in the form of a motor 121 is coupled to said slats 122 by a drive belt or band 124 coupled to a corresponding point on each slat not situated on the axis of the slat. Preferably the band or thread is coupled to the edge of each slat furthest from its axis. By exerting a force upon said band or thread at right angles to the parallel axes of the slats, the slats can be caused to rotate about their respective axes, that is to say, between the first and second configurations. An advantage of this approach is that the band or thread itself provides additional support to the slats, such that this approach is particularly suited to deck elements comprising slats of a particularly light construction or great length. As shown the motor 121 drives a vertical shaft 71 provided with two reels 72, 73. One extremity of the band 124 is fixed to one of these reels 72, and the other extremity to the other reel 73. The reels are so configured that when roted in the same direction, one pays out extra band, whilst the other reels it in. This brings about a resultant movement in the band as a whole, which in turn causes a shift in the angle of the slats

An advantage of this approach is that the movement of the band may be induced by means of a rotation in a vertical axis with respect to the installed horizontal deck element. It may be noted that as shown in FIG. 7 the slats 122 are in the second configuration, wherein the surfaces of adjacent slats are separated leaving said aperture at least partially open. As shown the slats are at an angle of approximately 45° with respect to the plane of the substantially planar member 410. The arrows 700 represent the flow of air from the datacenter below, through the aperture 427 and away. As mentioned above, the angle of the slats 422 may be set at a desired angle so that the opposition to the passage of air representative by the slats can be varied. In embodiments where the flow if coolant air is effected under pressure, either by means of a partial vacuum at the exhaust side, or an elevated pressure at the influx side, the rate of air flow through the datacenter may thus be controlled, or even cut off entirely, for example as a means of switching between different cooling strategies, or of preventing the arrival of oxygenated air in the event of a fire. To achieve this, the control unit 390 is preferably in communication with the various sensors situated about the data center necessary to determine the status of the datacenter, and may changes to the cooling provisions accordingly.

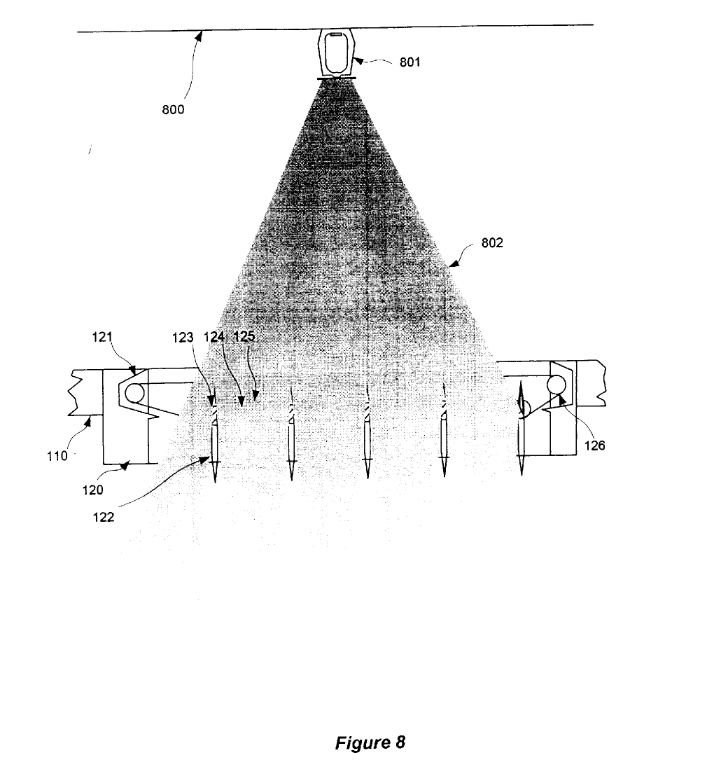

FIG. 8 shows the flow of extinguisher fluid through a datacenter deck element in accordance with an embodiment. As shown, there is provided a datacenter deck element substantially as described with regard to FIG. 4. It may be noted that as shown in FIG. 7 the slats 422 are in the second configuration, wherein the surfaces of adjacent slats are separated leaving said aperture at least partially open. As shown the slats are substantially orthogonal with respect to the plane of the substantially planar member 410, thereby presenting the minimum possible obstruction to the downward passage of extinguisher fluid from a sprinkler or similar outlet 801 mounted on the ceiling 800. The area 802 represents the flow of extinguisher fluid from the sprinkler 801 to the datacenter below, through the aperture 427 and down. Alternatively the slats might be set at an angle calculated to cause an optimum dispersion of the fluid into the space below, or to direct fluid in a particular direction, i.e. Towards or away from a particular piece of computer hardware below. As described above, the control unit 390 is in communication with smoke detectors, infra red sensors, thermometer, flame detectors or the like 391 distributed about the datacenter so as to identify the presence, location and type of fire, and to take steps accordingly.

According to certain embodiments the deck element may be adapted to present a minimal obstruction to the flow of extinguisher fluid. This may be achieved in any of the numerous ways which may occur to the skilled person. For example, each slat may coupled to its respecting actuation mechanism by means of a resilient member which in the absence of a substantial external force will permit the position of the slat via the actuation means. In the presence of a force exceeding a particular level capable of deflecting said resilient means, the resilient means will deflect rather than permitting the movement of the slat. Alternatively, the motor or other actuating means may detect the abnormal resistance to movement e.g. by detecting a current drain above a predetermined threshold, whereupon management electronic may automatically disconnect the motor, or set it to a fail-safe position. Still further, there may be provided a secondary sensor intended to detect the incidence of extinguisher fluid upon the deck element. For example, there may be provided a switch device adapted to be mechanically opened or shut by the force of fluid on a surface thereof. Finally, the actuation device may be coupled to the control circuitry of the sprinkler system as described hereafter.

The skilled person will appreciate that the sprinkler 801 may project water through a wider angle, and that extinguisher fluid from a given sprinkler may be cast beyond the edge of the aperture 427, indeed the sprinkler 801 need not be directly above the aperture 427. Furthermore, extinguisher fluid from a single sprinkler may be cast sufficiently widely to pass through a plurality of separate deck element apertures.

As soon as a sprinkler operates the datacenter deck element allows water fall to the floor;

When no sprinkler activity is required, the roof can be partially or totally closed; depending on the cooling strategy. The opening/closing of the roof when no sprinkler is in operation can be linearly controlled, i.e set to any desired intermediate position between open and closed.

According to a further embodiment, at least part of at least some slats is formed from a transparent or translucent material such as glass, PMMA (Poly Methyl Methacrylate), or polycarbonate, thereby ensuring that the datacenter deck element does not block the passage of light from lighting units mounted on the ceiling of the datacenter, or in any case above the computer hardware in such a way that light output would be blocked by conventional decking 241, 242.

According to a still further embodiment, at least part of at least some slats is treated to absorb electrostatic charge from the air moving through the datacenter deck element as described with reference to FIG. 7. Specifically, the parts of the slats in question, which are preferably parts of the slats which are in direct contact with the air flow, may be formed of a conductive material such as a metal or a plastic charged with conductive particles, threads etc, or a conductive polymer such as PEDOT:PSS. Alternatively, the parts of the slats in question may be coated with an antistatic agent such as an long-chain aliphatic amines and amides, quaternary ammonium salts, esters of phosphoric acid, polyethylene glycol esters, or polyols. Transparent or translucent coatings such as Indium tin oxide are particularly advantageous as being compatible with the preceding embodiment. In any case the parts of the slats in question are preferably electrically coupled to a ground, for example via an electrical connection of the motor 421, 621. A current path may advantageously be formed between the parts of the slats in question and the relevant connection of the motor by forming intervening parts of the datacenter deck element such as the mechanical coupling 625 from a conductive material.

According to a still further embodiment, the width and disposition of the slats may be optimised so as to interrupt the Brownian flow of air in the hot aisle by encouraging the establishment of a semi laminar flow in a chosen direction, for example from the hot aisle upward into the hot air evacuation system. In order to achieve this effect, datacenter deck element fitted over a hot aisle may be adapted such that a selected subset, e.g. half of the slats redirect airflow down-right to top-left, and the other part down-left to top right. This permits to centralize the airflow to be sucked in a limited section.

The differential inclination of different slats may be achieved either by coupling the slats to the actuator in such a way that the same actuation causes different movement in different slats, or by providing independent actuation for different groups of slats, or even for every slat individually.

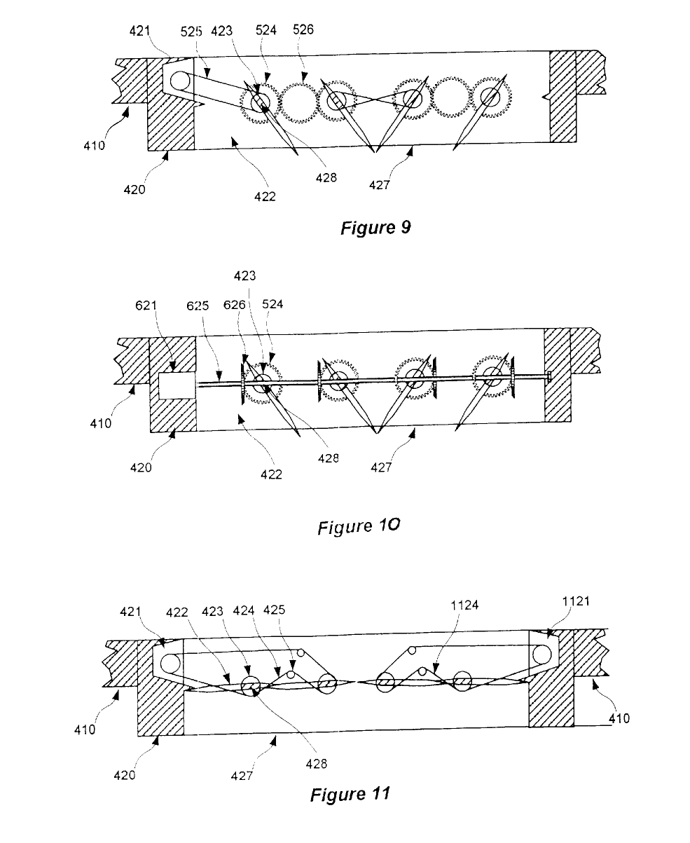

FIG. 9 shows a first configuration of a datacenter deck element adapted to promote laminar airflow. FIG. 9 shows an example of how the differential inclination of different slats may be achieved by coupling the slats to the actuator in such a way that the same actuation causes different movement in different slats. As shown, the datacenter deck element is similar to that described with respect to FIG. 5. However, as shown the datacenter deck element comprises an even number of slats, and in the place of the second gear between the two most central slats, there is provided a drive band in a crossed configuration so as reverse the direction of actuation between the two most central slats. Accordingly whilst the slats may still be aligned parallel each other in the second configuration as described above, actuation will cause the slats to diverge from the second configuration in opposite directions, so as to split the air flow.

FIG. 10 shows a second configuration of a datacenter deck element adapted to promote laminar airflow. FIG. 10 shows a further example of how the differential inclination of different slats may be, achieved by coupling the slats to the actuator in such a way that the same actuation causes different movement in different slats. As shown, the datacenter deck element is similar to that described with respect to FIG. 6. However, as shown the datacenter deck element comprises an even number of slats, more precisely, four, and the second crown gears on the rightmost pair of slats are situated to the right of the axes of the slats, whilst the second crown gears on the leftmost most pair of slats remain situated to the left of the axes of the slats. Accordingly whilst the slats may still be aligned parallel each other in the second configuration as described above, actuation will cause the slats to diverge from the second configuration in opposite directions, so as to split the air flow.

FIG. 11 shows a second configuration of a datacenter deck element adapted to promote laminar airflow. FIG. 11 shows a further example of how the differential inclination of different slats may be achieved by providing independent actuation for different groups of slats. As shown, the datacenter deck element is similar to that described with respect to FIG. 4. However, as shown the datacenter deck element comprises an even number of slats, more precisely. The leftmost pair of slats are actuated in exactly the same way as described with reference to FIG. 4, however the drive band 424 does not extend to the right most pair of slats, which instead are provided with an independent drive system mirroring that of the leftmost slats, with its own drive band 1124, its own motor 1121 etc. Accordingly the left and right hand sets of slats may be controlled in an entirely independent manner. As required, they both sets of slats may still be aligned parallel each other in the second configuration as described above, or set at opposing angles so as to split the air flow as shown, or indeed with one set in the first configuration an the other in the second, or any other combination as required.

Although described above with in accordance with a thermodynamic strategy in which datacenter deck elements in accordance with the present invention are provided in the hot aisle of a data center, it will be understood that they may equally be used in a datacenter which does not enforce a hot aisle/cool aisle configuration.

Still further, thermodynamic strategies for high density rooms are known which recommend also the provision of a cold aisle.

Where a cold aisle is thus provided, the datacenter deck element described above may alternatively or additionally be used in the air path of cold aisles, so as to control as necessary the flow of cold air top down into the cold aisle when the thermodynamic strategy requests a flexible cold air containment able to open when cold air is to be brought in vertically in the cold aisle, as well is providing the other functions described above.

While the actuating means in the forgoing example is an electric motor, it will be appreciated that the actuating means may comprise pneumatic, hydraulic, electromagnetic or any other means of actuation responsive to a remote signal.

Furthermore, in addition to the active types of actuating means mentioned above, there may also be envisaged passive actionating means such as a spring or other resilient biasing means, adapted to bias said slats towards a closed position, e.g. As shown in FIG. 4. This biasing should be sufficiently weak that the Brownian pressure of rising air is sufficient to partially own the slats, and the pressure of extinguisher fluid sufficient to open them entirely. According to this embodiment the control signal is thus the flow if coolant air or extinguisher fluid itself.

While the deck element of the present invention has been described in terms of a single set of slats each rotatatable about parallel axes in a single horizontal plane, there may equally be provided a deck element comprising a plurality of sets of slats, the axes of each set being homogenous with respect to those of the other sets. By way of example, the deck element may comprise four sets of slats each describing a right angled triangle, the axes of the slats of each triangle being parallel the hypotenuse of the respective triangle, with the slats being of graduated length, the longest being the slat closed to the hypotenuse and the shortest being that closest to the apex. By arranging the four triangular sets of slats with the apices touching, the four hypotenuses describe a square. A deck element constructed in this manner will thus correspond to a columnar air flow with a central vertical axis, which may correspond to the inlet of a cylindrical conduit situated above the deck element.

According to further embodiments there are provided datacenter deck element and a datacenter comprising the same, comprising a remotely actuated louvre or slatted aperture. The slats are actuated to adopt a vertical position in the event of a fire so as to permit the passage of water from a sprinkler or other ceiling mounted extinguisher. In normal circumstance the angle of the slats in controlled so as to establish desired coolant air flow conditions in the datacenter. The slats are preferably transparent so as to avoid interference with ceiling mounted lighting. The slats are preferably conductive or conductively coated so as to remove static charge, form the air flowing through the aperture. The slats may be independently actuated, or actuated in separate groups so at to adopt different configurations.

The slats may in particular be set in two groups at opposing angles so as to split the air flow and encourage a laminar rather than a Brownian movement of air in an adjacent volume.

1. A datacenter deck element comprising:
a planar member, positioned in a plane and comprising an aperture formed therein,
a plurality of slats, each of said slats rotatable about a longitudinal axis, the axes of said slats being arranged in parallel in the plane of said member,
actuating means coupled to said slats so as to cause said slats to rotate about their respective axes, in a first position wherein the surfaces of adjacent slats touch closing said aperture, and in a second position wherein the surfaces of adjacent slats are separate leaving said aperture at least partially open,
wherein said actuating means is adapted to cause said slats to rotate in response to a remote control signal.

2. The datacenter deck element of claim 1 wherein in said second position said slats are orthogonal to the plane of said member.

3. The datacenter deck element of claim 1 wherein said actuating means is an electric motor

4. The datacenter deck element of claim 1 wherein said actuating means is coupled to said slats by a drive belt.

5. The datacenter deck element of claim 1 wherein said remote control signal is generated by a fire detection system.

6. The datacenter deck element of claim 1 wherein said slats are translucent.

7. The datacenter deck element of claim 1 wherein said element is formed of materials that are unaffected by immersion in water.

8. The datacenter deck element of claim 1 wherein said element is formed of materials that are unaffected by immersion in fire extinguisher fluids.

9. The datacenter deck element of claim 1, wherein a first set of the slats redirects airflow down-right to top-left, and a second set of the slats redirects the airflow down-left to top-right so as to promote laminar air flow.

10. The datacenter deck element of claim 1, wherein said slats are asymmetrical with respect to their respective axes.

11. A datacenter comprising:
at least one piece of computer hardware,
at least one data center deck element, situated in a plane above said pieces of computer hardware, having an aperture formed in said deck, said deck comprising
a plurality of slats, each of said slats rotatable about a longitudinal axis, the axes of said slats being arranged in parallel in the plane of said member,
actuating means coupled to said slats so as to cause said slats to rotate about their respective axes, in a first position wherein the surfaces of adjacent slats touch closing said aperture, and in a second position wherein the surfaces of adjacent slats are separate leaving said aperture at least partially open,
wherein said actuating means is adapted to cause said slats to rotate in response to a remote control signal, and
control means adapted to generate a respective remote control signal for each of said data center deck elements.

12. The datacenter of claim 11 wherein conditions in said datacenter indicate the presence of a fire, and said control means is adapted to set at least one of the datacenter elements to said second position.

13. The datacenter of claim 12 wherein conditions in said datacenter indicate a normal condition, and said control means is adapted to set at least one of the datacenter elements to said first position.

14. (canceled)

15. The datacenter deck element of claim 1 wherein said actuating means is coupled to said slats by a series of gears.
